(19) United States
(12) Patent Application Publication
(10) Pub. No.: US 2008/0290440 A1
(43) Pub. Date: Nov. 27, 2008

(54) Photodiode for Image Sensor and Method of Manufacturing the Same

(76) Inventor: Byoung Su Lee, Jeollanam-do (KR)

Correspondence Address: IPLA P.A., 3580 WILSHIRE BLVD., 17TH FLOOR, LOS ANGELES, CA, 90010, US

(21) Appl. No.: 12/097,469

(22) PCT Filed: Dec. 4, 2006
(86) PCT No.: PCT/KR2006/005167

§ 371 Date: Jun. 13, 2008

(30) Foreign Application Priority Data
Dec. 28, 2005 (KR) 10-2005-0131324

(51) Int. Cl. H01L 31/0224

(52) U.S. Cl. 257/436; 438/72; 257/E31.122

(57) ABSTRACT

A photodiode for an image sensor capable of reducing reflection of light incident onto the photodiode and effectively absorbing transmitted light and a method of manufacturing the same are provided. In the photodiode for the image sensor, a silicon concavo-convex surface with a nano-thickness is formed by forming silicon oxide (SiO, x=0.5-1.5) layer on a silicon substrate and treating the silicon oxide layer with heat. A photodiode region is formed under the silicon layer having convexes and concaves. In this case, light absorptance increases because light reflected on the silicon concavo-convex surface is reincident onto another convex or concave. Therefore, an effective depth of the photodiode is larger than that of a planar photodiode, and accordingly, quantum efficiency of the photodiode increases.

### TECHNICAL FIELD

The present invention relates to a photodiode for an image sensor, and more particularly to a photodiode which has a structure capable of reducing light reflected on a silicon-based photodiode surface and increasing light absorbed in the photodiode and a method of manufacturing the same.

### BACKGROUND ART

An image sensor is used for measuring intensity of light. In general, the image sensor includes a plurality of photodiodes. The photodiodes are manufactured on the basis of silicon.

However, the silicon-based photodiode for the image sensor has a low absorptance of light. Accordingly, for example, a transmission depth is large in a red wavelength range.

A photo-sensor region is required to be deep due to the large transmission depth, thereby generating a crosstalk. Since a photodiode having a large area is required for a sufficient signal due to a low absorptance of light, it is difficult to miniaturize elements. Light reflected on a silicon surface is reincident onto a neighboring photodiode and causes a crosstalk.

A reflectance of light perpendicularly incident onto the silicon substrate is obtained by Equation 1 using a refractive index (n=4.75) and a loss factor (k=0.163) of silicon with respect to green light (wavelength of 450 nm).

$$R = \frac{{( {n}_{0} - n )}^{2} + {k}^{2}}{{( {n}_{0} + n )}^{2} + {k}^{2}} \qquad [ Equation 1 ]$$

Here, n₀ is a refractive index of a medium on the silicon substrate. When the light is incident onto the silicon substrate from air (n₀=1), the reflectance is about 0.43. When the light is incident onto the silicon substrate through a SiO₂ layer (n₀ ˜1.5), the reflectance is about 0.27. In order to reduce reflection, a general photodiode employs a method of inserting an anti-reflection coating (AR coating) layer such as a silicon nitride layer with a suitable thickness.

FIG. 1 illustrates a cross sectional view of a general photodiode for an image sensor with an AR coating layer.

A photodiode region 110, a doped layer 140 for separating the photodiode region 110 from a surface of the photodiode, and an AR coating layer 120 are formed on a silicon substrate 100. Light 150 that is incident onto the photodiode is reflected (160) or transmitted (170). A general AR coating layer effectively operates only on the perpendicularly incident light onto the surface. A reflectance is changed depending on a wavelength of the incident light.

In a visible light image sensor, the AR coating is generally performed with respect to green light with a wavelength of 550 nm. Since a wavelength used in the visible light image sensor ranges from 400 nm to 700 nm, the reflectances with respect to red and blue light are large, it is impossible to perform the AR coating with respect to all visible light required by the visible light image sensor.

FIG. 2 illustrates Red, Green, and Blue reflectance curves with respect to a thickness of a silicon nitride layer when light passing through a glass is incident onto the silicon through a silicon nitride layer.

As shown in FIG. 2, a silicon nitride layer with a specific thickness cannot operate as the AR coating layer with respect to all of Red (R), Green (G), and Blue (B) light. Accordingly, transmittances of RGB light are changed by the AR coating layer. Since an AR condition is not satisfied for incident light with a specific angle with respect to the photodiode, light with a specific wavelength is intensively reflected. Since the reflected light is incident onto a neighboring photodiode through various paths, the reflected light causes an optical crosstalk.

An ideal photodiode has to have the same reflectance with respect to RGB light. In addition, the light reflected light has not to be incident onto the neighboring photodiode. In order to shield the neighboring photodiode from the light that is incident onto the neighboring photodiode, a method of forming a shielding film on a region except the photodiode is employed.

In the photodiode having the structure shown in FIG. 1, the light that is incident onto the photodiode substantially perpendicularly passes through the photodiode. Accordingly, the path length of the light passing through the photodiode is substantially same as the depth of the photodiode. Since absorption of the light occurs while the light is passing through the photodiode, the length where the light is absorbed is substantially same as the depth of the photodiode.

The absorptance (k=0.163) of silicon is lower than that (k=2.18) of germanium. In order to absorb all light that is incident onto the photodiode, the photodiode has to have a large depth in the structure shown in FIG. 1 due to the low absorption of silicon, and the large depth of the photodiode causes noise, thereby deteriorating performance of the photodiode.

Photoelectrons generated by the light which is not absorbed in the photodiode and deeply penetrates the photodiode are absorbed in the neighboring photodiode through diffusion, thereby causing a crosstalk.

### DISCLOSURE OF INVENTION

### Technical Problem

The present invention provide a photodiode capable of reducing reflection of light regardless of an incident angle and a wavelength of the light incident onto a photodiode surface and increasing absorption of the light by increasing length of the path along which the light incident into the photodiode passes through the photodiode and a method of manufacturing the same.

### Technical Solution

According to an aspect of the present invention, there is provided a photodiode for an image sensor, the photodiode comprising: a photodiode region which is formed on a silicon substrate; a silicon concavo-convex surface which formed on the silicon substrate and the photodiode region in a concavo-convex shape; a doped region which is formed on the silicon concavo-convex surface to be separated the photodiode region from the surface of the photodiode; and a silicon oxide layer which is formed on the doped region.

According to another aspect of the present invention, there is provided a method of manufacturing a photodiode for an image sensor by forming a silicon concavo-convex surface, the method comprising: (a) forming a photodiode region on a silicon substrate; (b) forming a oxygen deficient silicon oxide layer on the photodiode region; (c) forming a silicon concavo-convex surface having a concavo-convex shape by treating the oxygen deficient silicon oxide layer with heat; and (d) forming a silicon oxide layer on the silicon concavo-convex surface.

### BRIEF DESCRIPTION OF THE DRAWINGS

The above and other features and advantages of the present invention will become more apparent by describing in detail exemplary embodiments thereof with reference to the attached drawings in which:

FIG. 1 illustrates a cross sectional view of an conventional photodiode;

FIG. 2 illustrates RGB reflectance curves with respect to a thickness of a silicon nitride layer;

FIG. 3 illustrates a cross sectional view of a photodiode for an image sensor according to an embodiment of the present invention;

FIG. 4 illustrates a three-dimensional (3D) cross sectional view of a photodiode for an image sensor according to an embodiment of the present invention; and

FIG. 5 illustrates a method of manufacturing a photodiode for an image sensor according to an embodiment of the present invention.

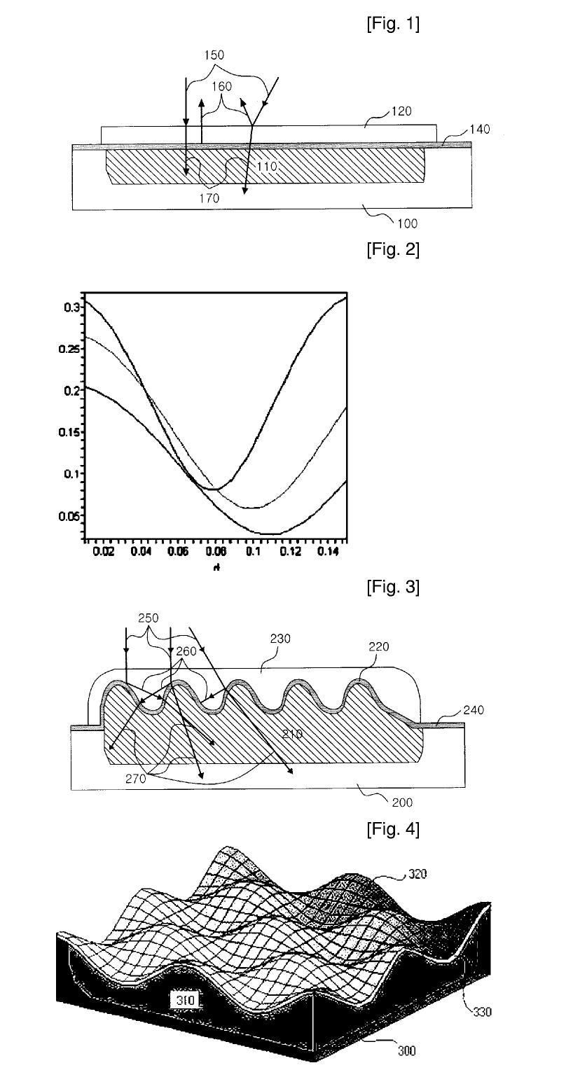

### BEST MODE FOR CARRYING OUT THE INVENTION

Hereinafter, the present will be described in detail with reference to accompanying drawings.

FIG. 3 schematically illustrates a cross sectional view of a silicon photodiode for an image sensor according to an embodiment of the present invention. The photodiode for the image sensor includes a photodiode region 210, a silicon concavo-convex surface 220, a silicon oxide layer 230, and a doped region 240.

The silicon concavo-convex surface 220 with a nano-thickness is formed on the photodiode region 210 formed on silicon substrate 200.

The doped region 240 for suppressing a leakage current by separating the photodiode region 210 from the surface of the photodiode is formed on the silicon concavo-convex surface 220 by doping.

The optically transmissive silicon oxide layer 230 is formed on the doped region 240.

A surface of a photodiode according to an embodiment of the present invention includes the silicon concavo-convex surface 220 with a nano-thickness (10 nm˜1000 nm). In addition, convexes and concaves of the silicon concavo-convex surface 220 have curvature angles lower than 90 degrees.

A part 270 of light 250 that is incident onto the silicon concavo-convex surface 220 is absorbed in the silicon substrate 200. Reflected light 260 is reincident onto a neighboring silicon concavo-convex surface 220. Accordingly, a reflection factor is a square of a reflectance with respect to light that is incident onto a plane. Since the light 270 that is incident into the silicon substrate 200 has a large incident angle and passes through the photodiode, the path along which the light 270 passes through the photodiode region 210 is longer than that in the conventional photodiode.

Intensity of light while the light passes through the silicon substrate 200 is determined by Equation 2.

I(x)=Iₒexp(−kx) [Equation 2]

Accordingly, intensity of light absorbed while the light passes along a path with a length L is determined by Equation 3.

α=1−exp(−kL) [Equation 3]

As the length L of the path along which the light passes through the photodiode increases, a quantum efficiency of converting the light into electric charges increases. Accordingly, the transmitted light 270 with a large incident angle has high quantum efficiency as compared with the perpendicularly transmitted light 170.

FIG. 4 illustrates a three-dimensional (3D) cross sectional view of a photodiode for an image sensor according to an embodiment of the present invention.

Referring to FIG. 4, a silicon concavo-convex surface 320 with a nano-thickness is formed on photodiode region 310 formed on silicon substrate 300. A doped region 330 for separating the photodiode region 310 from the surface of the photodiode is formed on the silicon concavo-convex surface 320.

Referring to FIG. 4, a part of the light incident onto the surface of the photodiode is absorbed, and reflected light is reincident onto a neighboring silicon concavo-convex surface 320, thereby increasing transmittance. The incident angle onto the silicon substrate increases, and a length of a path along which the incident light passes increase, thereby increasing quantum efficiency.

As described above, the photodiode for the image sensor according to the embodiment is manufactured by forming a photodiode region 210 on the silicon substrate 200, forming the silicon concavo-convex surface 220 with a concavo-convex shape on the surface of the photodiode region 210, and forming a silicon oxide layer 230 on the silicon concavo-convex surface 220. In addition, a leakage current can be suppressed by forming the doped region 240 for separating the photodiode region 210 from the surface of the photodiode on the silicon concavo-convex surface 220.

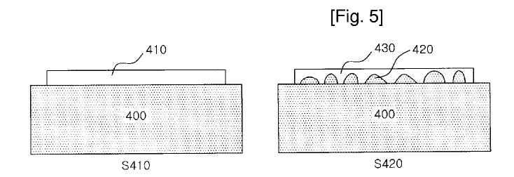

FIG. 5 illustrates a method of manufacturing a photodiode for an image sensor according to an embodiment of the present invention. The method comprises a step (S410) of forming a silicon oxide (SiOₓ, x=0.5˜1.5) layer 410 which is deficient in oxygen as compared with silicon dioxide (SiO₂) on a silicon surface and a step (S420) of forming a silicon concavo-convex surface by using a heat treatment.

When the oxygen deficient silicon oxide layer 410 is deposited on the silicon surface and treated with heat, the oxygen deficient silicon oxide is divided into a silicon (Si) phase and a silicon dioxide (SiO₂) phase. Since the substrate is made of silicon, the phase separation mainly occurs on the silicon surface. As a result, the silicon phase has a concavo-convex shape from the surface, and the silicon concavo-convex surface 420 is covered with the silicon oxide 430.

The thickness and the height of the silicon concavo-convex surface are determined by an oxygen concentration of the oxygen deficient silicon oxide 410, the thickness of the oxygen deficient silicon oxide 410, the heat treatment temperature, and the heat treatment time.

The doped region 240 of FIG. 3 for separating the photodiode region 210 of FIG. 3 from the surface of the photodiode can be formed by doping by the use of the silicon concavo-convex surface formed by the aforementioned method.

### INDUSTRIAL APPLICABILITY

A photodiode for an image sensor and a method of manufacturing the same according to an embodiment of the present invention can reduce an optical crosstalk by reducing a reflectance of light regardless of a wavelength and an incident angle of incident light and improve sensitivity by increasing a quantum efficiency by increasing the length of the path along which the light passes through the photodiode.

While the present invention has been particularly shown and described with reference to exemplary embodiments thereof, it will be understood by those skilled in the art that various changes in form and details may be made therein without departing from the spirit and scope of the present invention as defined by the appended claims.

1. A photodiode for an image sensor, the photodiode comprising:
a photodiode region which is formed on a silicon substrate;
a silicon concavo-convex surface which formed on the silicon substrate and the photodiode region in a concavo-convex shape;
a doped region which is formed on the silicon concavo-convex surface to be separated the photodiode region from the surface of the photodiode; and
a silicon oxide layer which is formed on the doped region.

2. The photodiode of claim 1, wherein convexes and concaves of the silicon concavo-convex surface have curvature angles lower than 90 degrees.

3. The photodiode of claim 1, wherein a thickness of the silicon concavo-convex surface ranges from 10 nm to 1000 nm.

4. A method of manufacturing a photodiode for an image sensor by forming a silicon concavo-convex surface, the method comprising:
(a) forming a photodiode region on a silicon substrate;
(b) forming a oxygen deficient silicon oxide layer on the photodiode region;
(c) forming a silicon concavo-convex surface having a concavo-convex shape by treating the oxygen deficient silicon oxide layer with heat; and
(d) forming a silicon oxide layer on the silicon concavo-convex surface.

5. The method of claim 4, further comprising forming a doped region on the silicon concavo-convex surface before forming the silicon oxide layer.

6. The method of claim 4, wherein in the oxygen deficient silicon oxide layer (SiO₂), x ranges from 0.5 to 1.5.

7. The method of claim 4, wherein a thickness and a height of the silicon concavo-convex surface can be determined by adjusting one or two of an oxygen concentration of the oxygen deficient silicon oxide layer, a thickness of the oxygen deficient silicon oxide layer, the heat treatment temperature, and the heat treatment time.

8. The method of claim 5, wherein in the oxygen deficient silicon oxide layer (SiO₂), x ranges from 0.5 to 1.5.

9. The method of claim 5, wherein a thickness and a height of the silicon concavo-convex surface can be determined by adjusting one or two of an oxygen concentration of the oxygen deficient silicon oxide layer, a thickness of the oxygen deficient silicon oxide layer, the heat treatment temperature, and the heat treatment time.
